(19) United States
(12) Patent Application Publication
(10) Pub. No.: US 2026/0059994 A1
(43) Pub. Date: Feb. 26, 2026

(54) METHOD OF MANUFACTURING SEMICONDUCTOR APPARATUS

(71) Applicant: CANON KABUSHIKI KAISHA, Tokyo (JP)

(72) Inventor: YOSHIHISA KAWAMURA, Kanagawa (JP)

(21) Appl. No.: 19/294,604

(22) Filed: Aug. 8, 2025

(30) Foreign Application Priority Data
Aug. 22, 2024 (JP) 2024-141223

(51) Int. Cl. H10K 71/00; H10K 39/32; H10K 59/10

(52) U.S. Cl. CPC H10K 71/00; H10K 39/32; H10K 59/10

(57) ABSTRACT

The present invention provides a method of manufacturing a semiconductor apparatus using a substrate including a first device region and a second device region where different kinds of devices are formed, comprising: selectively forming a first planarizing layer in the second device region where a surface height is lower than in the first device region; and collectively forming a second planarizing layer across the first device region and the second device region after the first planarizing layer is formed, wherein the first planarizing layer is formed by a planarization process of planarizing a composition supplied to the second device region by using a member having a flat surface.

### BACKGROUND

### Field of the Technology

The present disclosure relates to a method of manufacturing a semiconductor apparatus.

### Description of the Related Art

A plurality of devices such as image capturing devices or display devices can be manufactured from the same substrate. Japanese Patent Laid-Open No. 2024-82120 describes a method of forming a plurality of devices (semiconductor apparatus) on a substrate using a semiconductor wafer.

In the manufacture of a semiconductor apparatus, a plurality of kinds of devices may be formed on the same substrate. In this case, it is desirable to collectively form a layer arranged across the plurality of kinds of devices in a single process. However, if the surface height varies in formation of the plurality of kinds of devices, it can be difficult to form the layer in a single process.

### SUMMARY

The present disclosure provides a technique advantageous in manufacturing a plurality of kinds of devices from the same substrate.

According to one aspect of the present disclosure, there is provided a method of manufacturing a semiconductor apparatus using a substrate including a first device region and a second device region where different kinds of devices are formed, comprising: selectively forming a first planarizing layer in the second device region where a surface height is lower than in the first device region; and collectively forming a second planarizing layer across the first device region and the second device region after the first planarizing layer is formed, wherein the first planarizing layer is formed by a planarization process of planarizing a composition supplied to the second device region by using a member having a flat surface.

Features of the present disclosure will become apparent from the following description of embodiments with reference to the attached drawings. The following description of embodiments are described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a view showing a substrate including a plurality of device regions;

FIGS. 2A and 2B are views schematically showing a device manufacturing method according to the first embodiment;

FIGS. 3A and 3B are views schematically showing the device manufacturing method according to the first embodiment;

FIGS. 4A and 4B are views schematically showing the device manufacturing method according to the first embodiment;

FIGS. 5A and 5B are views schematically showing a device manufacturing method according to the second embodiment;

FIGS. 6A and 6B are views schematically showing the device manufacturing method according to the second embodiment;

FIGS. 7A and 7B are views schematically showing the device manufacturing method according to the second embodiment;

FIG. 8 is a view schematically showing an example of the arrangement of a planarization apparatus; and

FIGS. 9A to 9D are views for explaining a planarization process selectively performed on the second device region of a substrate.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

### First Embodiment

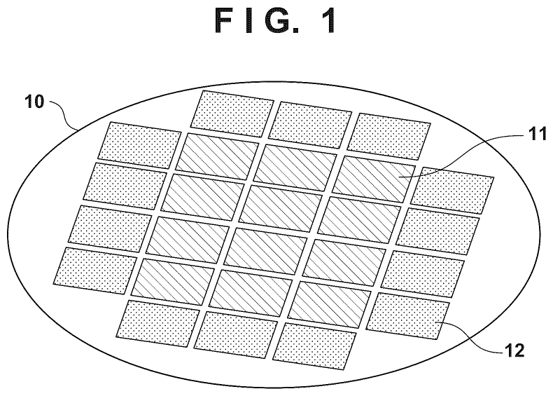

The first embodiment according to the present disclosure will be described. FIG. 1 shows a substrate 10 including a plurality of device regions. As the substrate 10, for example, a semiconductor wafer made of silicon or the like can be used. Each device region is, for example, a region of the substrate 10 where an image capturing device or a display device including a plurality of pixels is formed, which becomes one semiconductor chip. Each device region may include a stacked structure where a plurality of substrates, a plurality of layers, or a plurality of films are stacked.

FIG. 1 shows a plurality of kinds of device regions (a first device region 11 and a second device region 12) where different kinds of devices (semiconductor apparatus) are respectively formed. The first device region 11 is a region where, for example, a color image capturing device or a color display device (to be sometimes referred to as a color device hereinafter) is formed, and can be arranged in the central portion of the substrate 10. The second device region 12 is a region where, for example, a monochrome image capturing device or a monochrome display device (to be sometimes referred to as a monochrome device hereinafter) is formed, and can be arranged in the peripheral portion of the substrate 10.

In this manner, in a case where a color device and a monochrome device are formed in the same substrate 10, a color filter layer is provided in the first device region 11 but the color filter layer is not provided in the second device region 12. That is, after the color filter layer is formed in the first device region 11, the surface height is different between the first device region 11 and the second device region 12. Hence, after the color filter layer is formed, it can be difficult to collectively form a common layer or film across the first device region 11 and the second device region 12 in a single process.

Therefore, in this embodiment, for the second device region 12 where the surface height is lower than in the first device region 11 formed with the color filter layer, a planarizing layer (first planarizing layer) is selectively formed by a planarization process. In this specification, the planarization process is defined as a “process of planarizing a composition using a member having a flat surface”, and used to, for example, form a planarizing layer by planarizing the composition supplied to the second device region 12. Details of the planarization process and an apparatus (planarization apparatus) therefor will be described later.

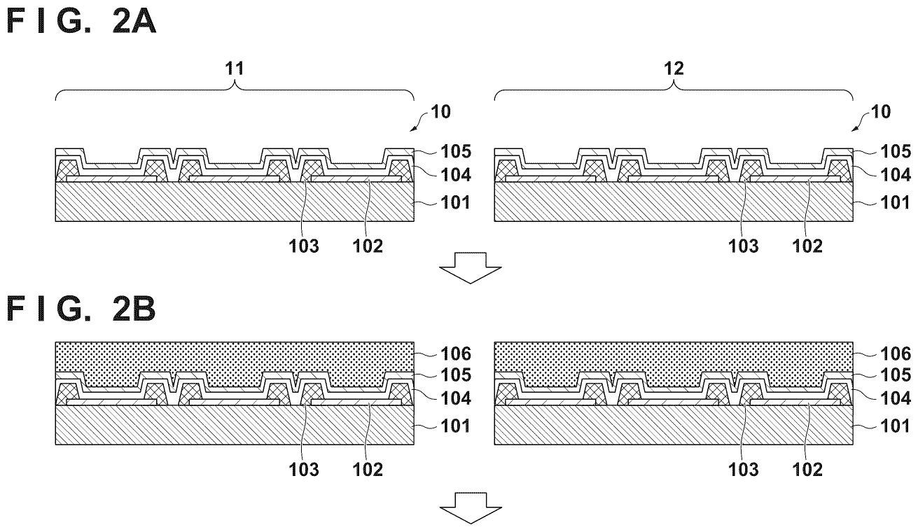

An example of a device manufacturing method according to this embodiment will be described with reference to FIGS. 2A to 4B. FIGS. 2A to 4B are views schematically showing a device manufacturing method in the first device region 11 and the second device region 12. In this embodiment, the first device region 11 where a color device is formed may be referred to as the “color device region 11”, and the second device region 12 where a monochrome device is formed may be referred to as the “monochrome device region 12”. In FIGS. 2A to 4B, the color device region 11 and the monochrome device region 12 are shown separately, but the color device region 11 and the monochrome device region 12 are provided in the same substrate 10.

Step S10 shown in FIG. 2A is a step of preparing the substrate 10, and referred to explain the arrangement of each of the color device region 11 and the monochrome device region 12 in the substrate 10. In each of the color device region 11 and the monochrome device region 12 in the substrate 10, a structure 101, a lower electrode 102, an insulating layer 103, an organic layer 104 including a light emitting layer, and an upper electrode 105 have already been formed. In this embodiment, the arrangement of the structure 101, the lower electrode 102, the insulating layer 103, the organic layer 104, and the upper electrode 105 is the same in the color device region 11 and the monochrome device region 12.

The structure 101 can include a switching element, such as a transistor for driving the pixel, formed in the substrate 10, an insulating layer, a wiring pattern layer, and a conductor such as a contact plug. The structure 101 can include, for example, an insulating film containing silicon oxide or the like, and a wiring pattern containing copper, aluminum, or the like as a main component.

The lower electrode 102 is arranged on the structure 101 for each pixel. In this specification, “on” indicates the direction from the substrate 10 to a lens array 110 (to be described later). The lower electrode 102 can function as the anode or cathode of a light emitting element included in each pixel. The lower electrode 102 may have a role as a reflection layer for light generated by the light emitting layer included in the organic layer 104. Hence, a metal such as aluminum or silver having a relatively high reflectance, or an alloy thereof can be used for the lower electrode 102.

The insulating layer 103 can be formed to cover the end portion of the lower electrode 102. The insulating layer 103 may be called a pixel isolation film or a bank. An insulating material such as silicon nitride, silicon oxynitride, or silicon oxide can be used for the insulating layer 103. The light emission position of each pixel can be defined by the position of the lower electrode 102 exposed from an opening portion provided in the insulating layer 103.

The organic layer 104 is arranged to cover the lower electrode 102 and the insulating layer 103. The organic layer 104 may be formed from a plurality of layers including the light emitting layer. The plurality of layers may include a hole injection layer, a hole transport layer, an electron blocking layer, a light emitting layer, a hole blocking layer, an electron transport layer, an electron injection layer, and the like.

The upper electrode 105 is arranged on the organic layer 104 to be across a plurality of pixels. The upper electrode 105 can function as the cathode or anode of the light emitting element included in each pixel. The upper electrode 105 is a conductive layer having a property (light transmissive property) of transmitting light emitted from the light emitting layer included in the organic layer 104. An alloy containing silver or magnesium as a main component, or a transparent conductive material such as indium tin oxide (ITO) can be used for the upper electrode 105.

In step S11 shown in FIG. 2B, a lower planarizing layer 106 is collectively formed on the substrate 10 across the color device region 11 and the monochrome device region 12. The lower planarizing layer 106 is a layer for planarizing the unevenness of the upper surface of the substrate 10, and can be formed by, for example, spin-coating an organic material onto the substrate 10 using a spin coating method. With this, the lower planarizing layer 106 having a flat surface (upper surface) can be collectively formed over the entire area of the substrate 10 including the color device region 11 and the monochrome device region 12. The organic material used for the lower planarizing layer 106 can be a material having a property (light transmissive property) of transmitting light emitted from the light emitting layer included in the organic layer 104, and capable of being spin-coated.

Here, an example where the lower planarizing layer 106 is formed using a spin coating method is described in this embodiment, but the lower planarizing layer 106 is not limited to this and may be formed using a method other than the spin coating method as long as a layer having a flat surface can be formed. For example, the lower planarizing layer 106 may be formed by a planarization process (to be described later) using a member having a flat surface. In the planarization process in this case, a member having a flat surface that can contact the entire area of the substrate 10 can be used. In a case where a protection layer is formed on the upper electrode 105, the lower planarizing layer 106 can be formed on the protection layer. The protection layer is arranged to suppress diffusion, to the organic layer 104 and the structure 101, of moisture and impurities from the outside. For example, silicon nitride, silicon oxide, aluminum oxide, or the like can be used for the protection layer.

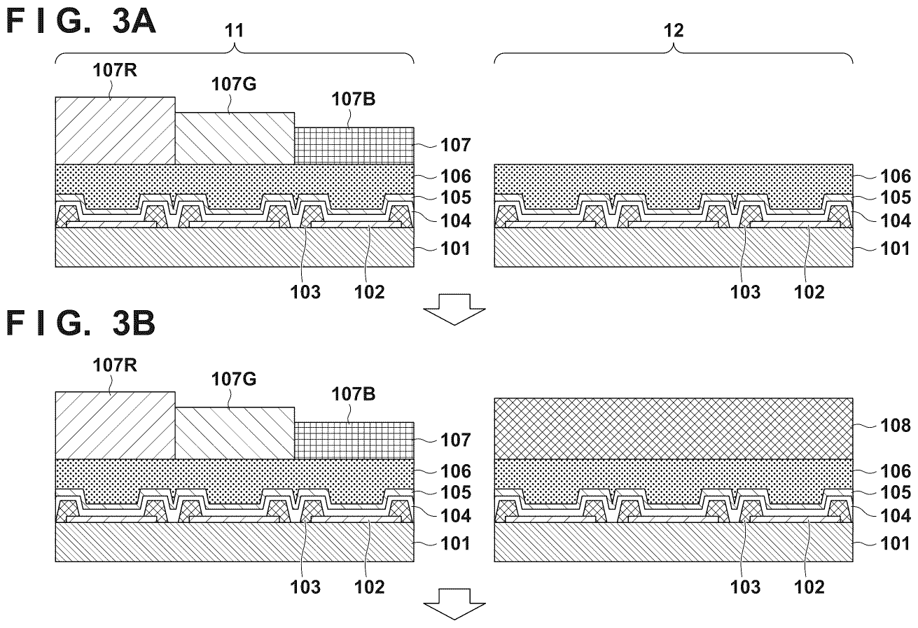

In step S12 shown in FIG. 3A, a color filter layer 107 is formed on the lower planarizing layer 106 in the color device region 11. The color filter layer 107 may include a plurality of kinds of filters each of which transmits (or absorbs) light of a specific frequency band. For example, in the color device region 11, different kinds (colors) of filters can be respectively provided for the pixels. The color filter layer 107 may include, for example, three kinds of filters including a filter 107R which transmits red light, a filter 107G which transmits green light, and a filter 107B which transmits blue light. In order to adjust the transmittances of the filters, the plurality of kinds of filters 107R, 107G, and 107B in the color filter layer 107 may have thicknesses different from each other. Note that in this step S12, the color filter layer 107 is not formed in the monochrome device region 12.

In step S13 shown in FIG. 3B, a planarizing layer 108 (first planarizing layer) is formed on the lower planarizing layer 106 in the monochrome device region 12. The planarizing layer 108 is a layer for reducing the difference in surface height between the color device region 11 and the monochrome device region 12, which occurs due to formation of the color filter layer 107 in step S12 described above, and selectively formed in the monochrome device region 12. More specifically, the planarizing layer 108 is formed in the monochrome device region 12 by a planarization process (to be described later) so as to reduce the difference between the surface height of the color filter layer 107 in the color device region 11 and the surface height of the planarizing layer 108 in the monochrome device region 12. The planarizing layer 108 is preferably formed such that its surface height approaches the surface height of the color filter layer 107. If the color filter layer 107 is formed from a plurality of kinds of filters having thicknesses different from each other, the planarizing layer 108 is preferably formed such that its surface height is between the highest position and the lowest position of the surface height of the color filter layer 107. Here, the composition (material) used for the planarizing layer 108 can have a property (light transmissive property) of transmitting light emitted from the light emitting layer included in the organic layer 104.

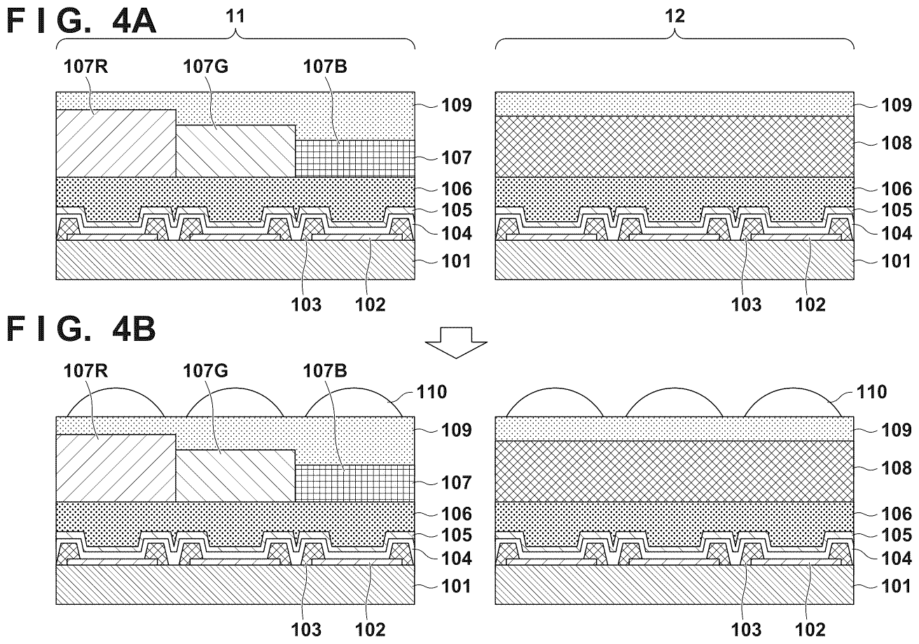

In step S14 shown in FIG. 4A, an upper planarizing layer 109 (second planarizing layer) is collectively formed across the color device region 11 and the monochrome device region 12. The upper planarizing layer 109 is a layer for planarizing the surface of the layer (the color filter layer 107 or the planarizing layer 108) under the upper planarizing layer 109, and can be formed by, for example, spin-coating an organic material using a spin coating method. With this, the upper planarizing layer 109 having a flat surface (upper surface) can be collectively formed over the entire area of the substrate 10 including the color device region 11 and the monochrome device region 12. The upper planarizing layer 109 is formed on the color filter layer 107 in the color device region 11, and formed on the planarizing layer 108 in the monochrome device region 12.

The organic material used for the upper planarizing layer 109 can be a material having a property (light transmissive property) of transmitting light emitted from the light emitting layer included in the organic layer 104, and capable of being spin-coated. The organic material used for the upper planarizing layer 109 may be the same as the organic material used for the lower planarizing layer 106. Here, in this embodiment, an example is described in which the upper planarizing layer 109 is formed using a spin coating method, but the upper planarizing layer 109 is not limited to this and may be formed using a method other than the spin coating method as long as a layer having a flat surface can be formed. For example, the upper planarizing layer 109 may be formed by the planarization process (to be described later) using a member having a flat surface. In the planarization process in this case, a member having a flat surface that can contact the entire area of the substrate 10 can be used.

In step S15 shown in FIG. 4B, a lens array 110 (microlens array) is formed on the upper planarizing layer 109 for each of the color device region 11 and the monochrome device region 12. The lens array 110 is formed such that one microlens is arranged for each pixel. For example, after a lens material is formed on the upper planarizing layer 109 over the entire area of the substrate 10 including the color device region 11 and the monochrome device region 12, a photoresist applied onto the lens material is patterned into a lens shape by a photolithography step. Then, by etching the lens material while using the photoresist as a mask, the lens array 110 can be formed on the upper planarizing layer 109.

As described above, in this embodiment, the difference in surface height between the color filter layer 107 in the color device region 11 and the planarizing layer 108 in the monochrome device region 12 is reduced by selectively forming the planarizing layer 108 in the monochrome device region 12. Selectively forming the planarizing layer 108 in the monochrome device region 12 can be implemented by a planarization process using a member having a flat surface. With this, the surface flatness of the upper planarizing layer 109 collectively formed across the color device region 11 and the monochrome device region 12 improves. Accordingly, it is possible to form the lens array 110 collectively and accurately on the upper planarizing layer 109 across the color device region 11 and the monochrome device region 12.

### Second Embodiment

The second embodiment according to the present disclosure will be described. This embodiment basically takes over the first embodiment, and matters not mentioned below can follow the first embodiment.

In the first embodiment described above, an example has been described in which a difference in surface height occurs between the first device region 11 (color device region) and the second device region 12 (monochrome device region) due to formation of the color filter layer 107 in the first device region 11. On the other hand, in this embodiment, an example will be described in which a difference in surface height of a substrate 10 occurs between a first device region 11 and a second device region 12. Also in a case where a difference in surface height of the substrate 10 occurs, it can be difficult to collectively form a common layer or film across the first device region 11 and the second device region 12 in a single process. Therefore, in this embodiment, a planarizing layer 111 is selectively formed in the second device region 12 by a planarization process using a member having a flat surface so as to reduce the difference in surface height of the substrate 10 between the first device region 11 and the second device region 12. In this embodiment, the second device region 12 can be defined as a region where the surface height of the substrate 10 is lower than in the first device region 11.

Here, in this embodiment, both the first device region 11 and the second device region 12 are described as regions where color devices are formed, but they are not limited to this and may be regions where monochrome devices are formed. Alternatively, one of the first device region 11 and the second device region 12 may be a region where a color device is formed, and the other may be a region where a monochrome device is formed. In this case, the planarizing layer 108 described in the first embodiment may be applied. The first device region 11 is not limited to be arranged in the central portion of the substrate 10, and the second device region 12 is not limited to be arranged in the peripheral portion of the substrate 10.

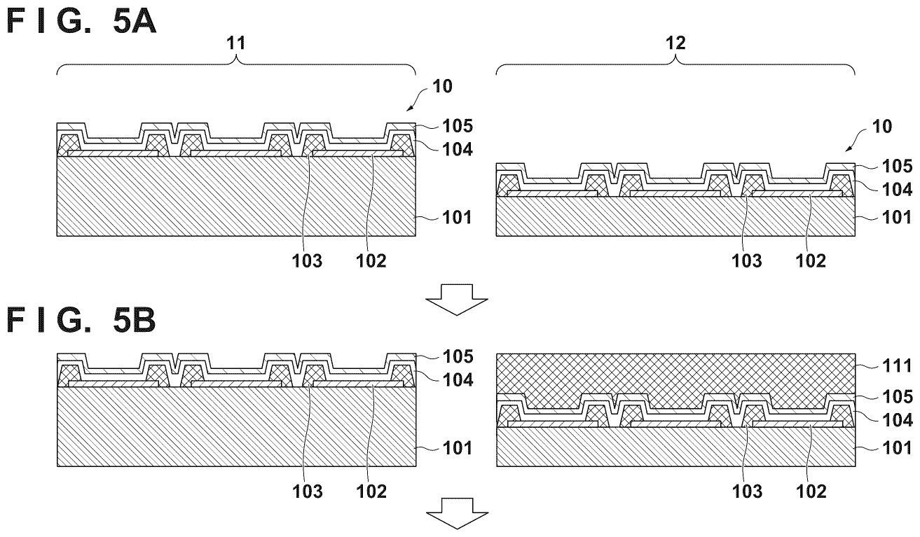

An example of a device manufacturing method according to this embodiment will be described with reference to FIGS. 5A to 7B. FIGS. 5A to 7B are views schematically showing a device manufacturing method in the first device region 11 and the second device region 12. In FIGS. 5A to 7B, the first device region 11 and the second device region 12 are shown separately, but the first device region 11 and the second device region 12 are provided in the same substrate 10.

Step S20 shown in FIG. 5A is a step of preparing the substrate 10, and referred to explain the arrangement of each of the first device region 11 and the second device region 12 in the substrate 10. In each of the first device region 11 and the second device region 12 in the substrate 10, a structure 101, a lower electrode 102, an insulating layer 103, an organic layer 104 including a light emitting layer, and an upper electrode 105 have already been formed. The arrangement of the structure 101, the lower electrode 102, the insulating layer 103, the organic layer 104, and the upper electrode 105 is as described in the first embodiment, and is the same in the first device region 11 and the second device region 12. Note that, in this embodiment, the number of stacked layers (for example, the number of wiring layers) forming the structure 101 is smaller in the second device region 12 than in the first device region 11, so that the surface height of the substrate 10 is lower in the second device region 12 than in the first device region 11.

In step S21 shown in FIG. 5B, the planarizing layer 111 (first planarizing layer) is formed on the substrate 10 in the second device region 12. The planarizing layer 111 is a layer for reducing the difference in surface height of the substrate 10 between the first device region 11 and the second device region 12, and selectively formed in the second device region. More specifically, the planarizing layer 111 is formed in the second device region 12 by a planarization process (to be described later) so as to reduce the difference between the surface height of the substrate 10 in the first device region 11 and the surface height of the planarizing layer 111 in the second device region 12. The planarizing layer 111 is preferably formed such that its surface height approaches the surface height of the substrate 10 in the first device region 11. If the substrate 10 includes a step in the first device region 11, the planarizing layer 111 is preferably formed such that its surface height is between the highest position and the lowest position of the step.

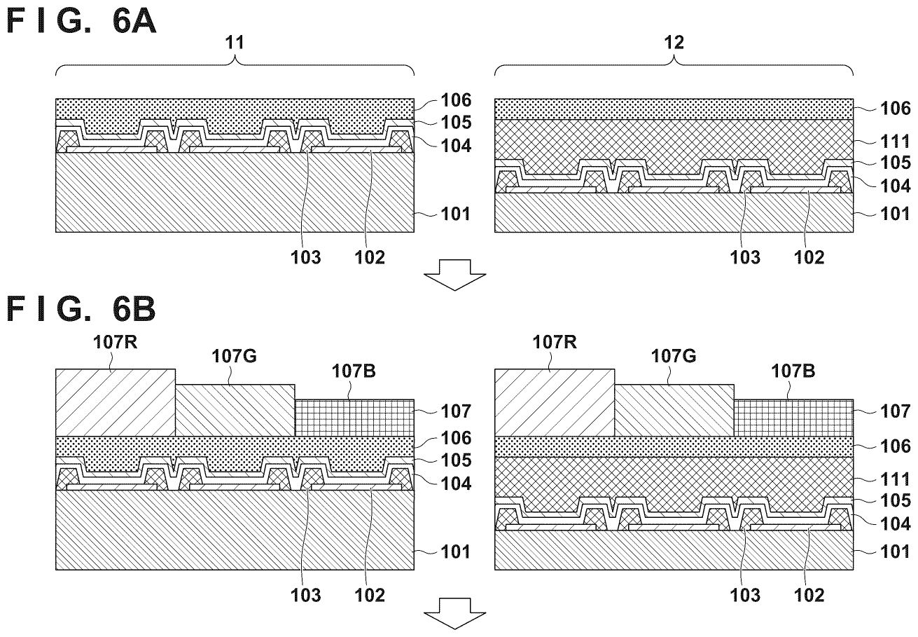

In step S22 shown in FIG. 6A, a lower planarizing layer 106 (second planarizing layer) is collectively formed across the first device region 11 and the second device region 12. The lower planarizing layer 106 is a layer for planarizing the surface of the layer (the substrate 10 or the planarizing layer 111) under the lower planarizing layer 106, and can be formed by, for example, spin-coating an organic material using a spin coating method. With this, the lower planarizing layer 106 having a flat surface (upper surface) can be collectively formed over the entire area of the substrate 10 including the first device region 11 and the second device region 12. The lower planarizing layer 106 is formed on the substrate 10 in the first device region 11, and formed on the planarizing layer 111 in the second device region 12. Note that a material and the like of the lower planarizing layer 106 are as described in step S11 in the first embodiment, so that a detailed description will be omitted here.

In step S23 shown in FIG. 6B, a color filter layer 107 is formed on the lower planarizing layer 106 in each of the first device region 11 and the second device region 12. The color filter layer 107 can include, for example, a filter 107R which transmits red light, a filter 107G which transmits green light, and a filter 107B which transmits blue light. Note that the arrangement and the like of the color filter layer 107 are as described in step S12 in the first embodiment, so that a detailed description will be omitted here.

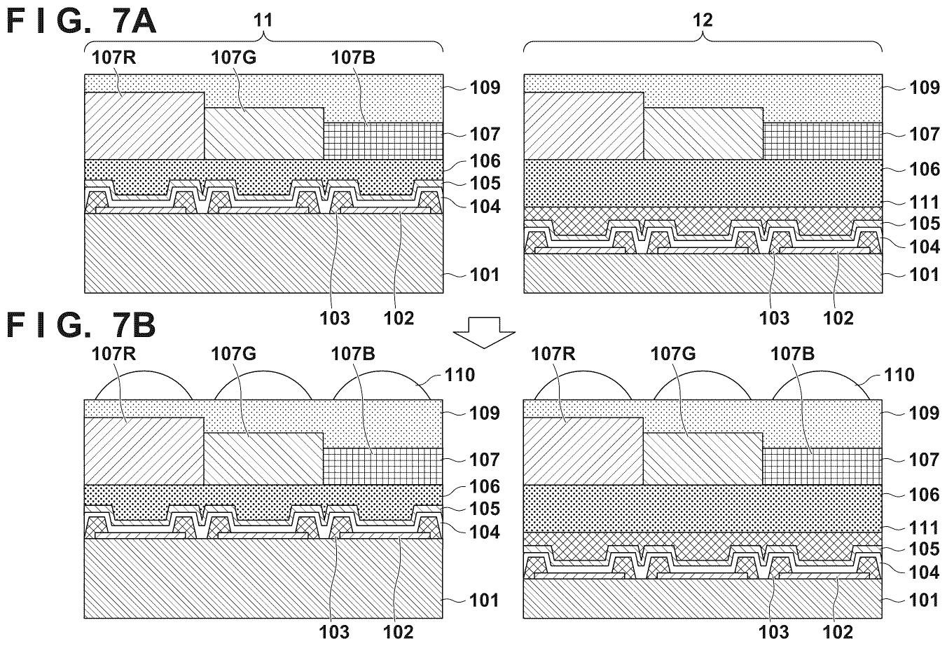

In step S24 shown in FIG. 7A, an upper planarizing layer 109 is collectively formed across the first device region 11 and the second device region 12. The upper planarizing layer 109 is a layer for planarizing the surface of the layer (the color filter layer 107) under the upper planarizing layer 109, and can be formed by, for example, spin-coating an organic material using a spin coating method. With this, the upper planarizing layer 109 having a flat surface (upper surface) can be formed over the entire area of the substrate 10 including the first device region 11 and the second device region 12. The upper planarizing layer 109 is formed on the color filter layer 107 in each of the first device region 11 and the second device region 12. Note that the material and the like of the upper planarizing layer 109 are as described in step S14 in the first embodiment, so that a detailed description will be omitted here.

In step S25 shown in FIG. 7B, a lens array 110 (microlens array) is formed on the upper planarizing layer 109 for each of the first device region 11 and the second device region 12. The lens array 110 is formed such that one microlens is arranged for each pixel. Note that the arrangement, forming method, and the like of the lens array 110 are as described in step S15 in the first embodiment, so that a detailed description will be omitted here.

As described above, in this embodiment, the difference in surface height between the first device region 11 and the second device region 12 is reduced by selectively forming the planarizing layer 111 in the second device region 12 where the surface height of the substrate 10 is lower than in the first device region 11. Selectively forming the planarizing layer 111 in the second device region 12 can be implemented by a planarization process using a member having a flat surface. With this, the surface flatness of the lower planarizing layer 106 collectively formed across the first device region 11 and the second device region 12 improves. Accordingly, it is possible to form the color filter layer 107 (respective filters) collectively and accurately on the lower planarizing layer 106 across the first device region 11 and the second device region 12. In addition, the surface flatness of the upper planarizing layer 109 collectively formed across the first device region 11 and the second device region 12 also improves. Accordingly, it is possible to form the lens array 110 collectively and accurately on the upper planarizing layer 109 across the first device region 11 and the second device region 12.

### Embodiment of Planarization Process

An embodiment of a planarization process according to the present disclosure will be described below. As described above, the planarization process is a process of planarizing a composition using a member having a flat surface, and can include an Inkjet-based Adaptive Planarization (IAP). The planarization process can be applied to formation of the planarizing layer 108 in step S13 in the first embodiment, and formation of the planarizing layer 111 in step S21 in the second embodiment. A member (mold) having a flat surface may be called a planarization member, a superstrate, or a plane template, and may be referred to as a “planarization member”below.

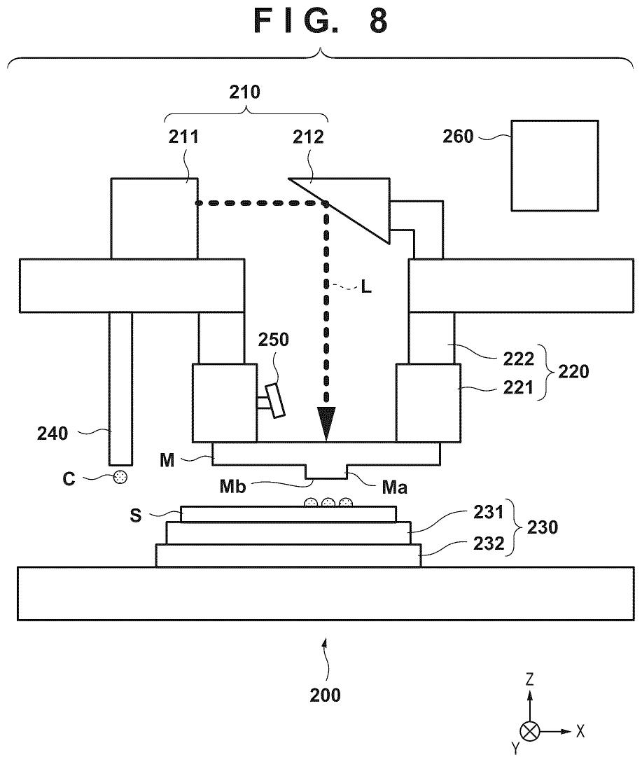

FIG. 8 is a view schematically showing an example of the arrangement of a planarization apparatus 200 that executes a planarization process. In FIG. 8, directions will be indicated on an XYZ coordinate system in which a surface parallel to the surface (holding surface) for holding a substrate S is defined as an X-Y plane. The planarization apparatus 200 can include a curing unit 210, a head 220 that holds a planarization member M, a stage 230 that holds the substrate S, a supply unit 240 that supplies a composition C onto the substrate S, a measurement unit 250, and a control unit 260.

The substrate S corresponds to the substrate 10 in the first and second embodiments, and may be understood as a substrate after one or more layers are formed on the substrate 10. As shown in FIG. 1, a plurality of device regions are provided in the substrate S. The plurality of device regions include a plurality of kinds of device regions (a first device region 11 and a second device region 12) where different kinds of devices are respectively formed. In this embodiment, a planarization process can be individually performed by the planarization apparatus 200 for each second device region 12 of the substrate S.

As the composition C used in the planarization process, a curable composition (to be also referred to as a resin in an uncured state) to be cured by receiving curing energy is used. An example of the curing energy that is used is electromagnetic waves, heat, or the like. As the electromagnetic waves, for example, infrared light, visible light, ultraviolet light, and the like selected from the wavelength range of 10 nm (inclusive) to 1 mm (inclusive) is used. The curable composition is a composition cured by light irradiation or heating. Among these, a photo-curable composition cured by light irradiation contains at least a polymerizable compound and a photopolymerization initiator, and may further contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The viscosity (the viscosity at 25° C.) of the viscous material is, for example, from 1 mPa·s (inclusive) to 100 mPa·s (inclusive).

When a photo-curable composition is used, the planarization member M is formed of a light transmissive material. As a material for the planarization member, for example, glass, quartz, Polymethyl Methacrylate (PMMA), polycarbonate resin, or the like is used. The planarization member M includes a protrusion portion Ma in which a surface on the substrate S side is formed as a flat surface Mb. In order to perform the planarization process on the second device region 12 where the surface height is lower than in the first device region 11, the protrusion portion Ma has almost the same dimension (X and Y directions) as one device region, and is formed to have a shape (mesa shape) protruding toward the substrate S. The flat surface Mb is a surface for planarizing the composition C by contacting the composition C on the substrate S.

The curing unit 210 (irradiation unit) cures the composition C by irradiating the composition C on the substrate S with light L. The curing unit 210 in this embodiment includes a light source unit 211 that emits the light L for curing the composition C on the substrate S, and an optical member 212 for guiding the light L emitted from the light source unit 211 to the composition C on the substrate S, and irradiates the composition C on the substrate S with the light L via the planarization member M. The optical member 212 may include an optical element for adjusting (shaping) the shape of the light L emitted from the light source unit 211 to a shape suitable for the planarization process.

The head 220 can include a member holding unit 221 that holds the planarization member M by a vacuum suction force or the like, and a member driving unit 222 that drives the planarization member M by driving the member holding unit 221. The member holding unit 221 and the member driving unit 222 include an opening region where the central portion (inside) is open so that the light L emitted from the curing unit 210 is applied to the composition C on the substrate S. The member driving unit 222 drives the member holding unit 221 (planarization member M) in the Z direction to bring the planarization member M into contact with the composition C on the substrate S and separate the planarization member M from the cured composition C.

The stage 230 can include a substrate holding unit 231 that holds the substrate S by a vacuum suction force or the like, and a substrate driving unit 232 that drives the substrate S by driving the substrate holding unit 231. The substrate driving unit 232 drives the substrate holding unit 231 (substrate S) in the X and Y directions to perform alignment between the planarization member M and the substrate S.

Here, the head 220 (member driving unit 222) and the stage 230 (substrate driving unit 232) form a relative driving unit that relatively drives the planarization member M and the substrate S. That is, relative driving (Z direction) between the planarization member M and the substrate S for bringing the planarization member M into contact with the composition C on the substrate S and separating the planarization member M from the cured composition C can be performed by at least one of the head 220 and the stage 230. In addition, relative driving (X and Y directions) between the planarization member M and the substrate S for performing alignment between the planarization member M and the substrate S can be performed by at least one of the head 220 and the stage 230.

The supply unit 240 includes a dispenser that discharges (drops) the composition C as a plurality of droplets, and supplies the composition C onto the substrate S by causing the dispenser to discharge the composition C. For example, in a state in which the substrate S is moved by the stage 230 in the X and Y directions below the supply unit 240, the supply unit 240 discharges the composition C as a plurality of droplets. With this, the composition C can be supplied (arranged) onto the substrate S as the plurality of droplets.

The measurement unit 250 includes a scope that detects a mark provided in the planarization member M and a mark provided in the substrate S, and measures the relative position between the planarization member M and the substrate S in the X and Y directions based on the positional shift between the marks detected by the scope. The measurement result of the measurement unit 250 can be used to selectively supply the composition C to the second device region 12 of the substrate S and bring the planarization member M (flat surface Mb) into contact in the second device region 12 of the substrate S.

The control unit 260 is formed by, for example, a computer (information processing apparatus) including a processor such as a Central Processing Unit (CPU) and a storage unit such as a memory, and controls the planarization process by controlling the respective units of the planarization apparatus 200. The control unit 260 may be formed by, for example, a PLD (a short for Programmable Logic Device) such as an FPGA (a short for Field Programmable Gate Array), an ASIC (a short for Application Specific Integrated Circuit), a general-purpose computer with programs installed therein, or a combination of some or all of these.

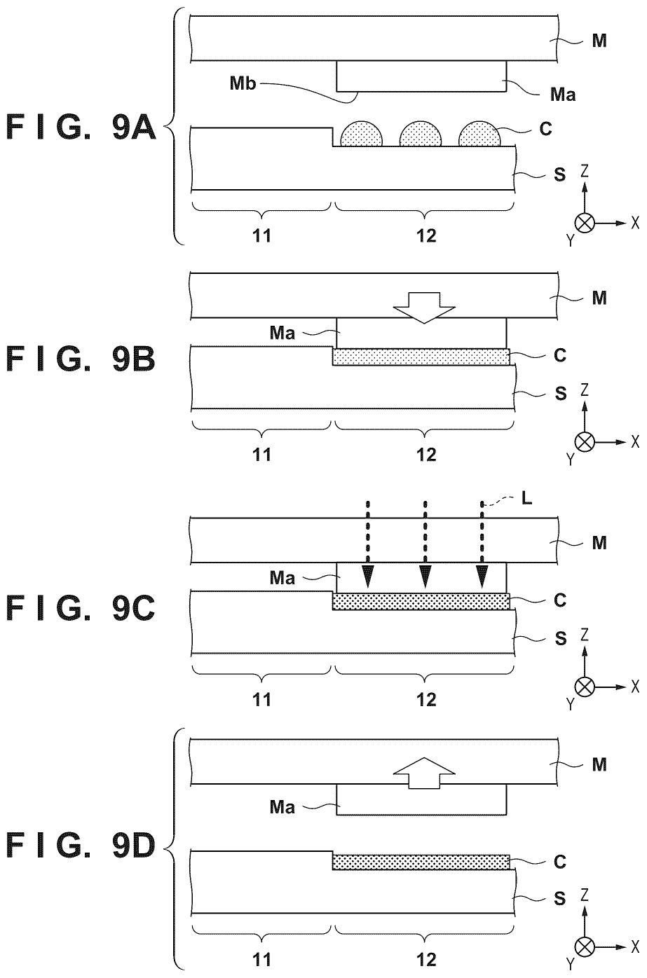

FIGS. 9A to 9D are views for explaining a planarization process selectively performed on the second device region 12 of the substrate S. The planarization process shown in FIGS. 9A to 9D is a process performed in the planarization apparatus 200, and performed by the control unit 260 comprehensively controlling the respective units of the planarization apparatus 200. Note that, for the sake of illustrative simplicity, FIGS. 9A to 9D schematically show only the planarization member M and the substrate S, and illustration of the respective units of the planarization apparatus 200 is omitted.

In the planarization process on the second device region 12, as shown in FIG. 9A, the composition C is first supplied as a plurality of droplets to the second device region 12 by the supply unit 240. Then, as shown in FIG. 9B, the planarization member M is driven in the −Z direction by the head 220 (member driving unit 222) to bring the flat surface Mb of the planarization member M (protrusion portion Ma) into contact with the composition C on the second device region 12. With this, the composition C on the second device region 12 spreads along the flat surface Mb of the planarization member M and forms a liquid film.

After the composition C spreads over the second device region 12, as shown in FIG. 9C, in a state in which the planarization member M and the composition C on the second device region 12 are in contact with each other, the curing unit 210 irradiates the composition C with the light L to cure the composition C. Then, as shown in FIG. 9D, the planarization member M is driven in the +Z direction by the head 220 (member driving unit 222) to separate the planarization member M from the cured composition C in the second device region 12. With this, a planarizing layer (for example, the planarizing layer 108 in the first embodiment or the planarizing layer 111 in the second embodiment) can be formed in the second device region 12.

Here, the above-described planarization process may be used when collectively forming the lower planarizing layer 106 across the first device region 11 and the second device region 12 in step S11 in the first embodiment and/or step S22 in the second embodiment. Similarly, the above-described planarization process may be used when collectively forming the upper planarizing layer 109 across the first device region 11 and the second device region 12 in step S14 in the first embodiment and/or step S24 in the second embodiment. In the planarization process in these cases, the planarization member M having the flat surface Mb with a dimension capable of contacting the entire area of the substrate S can be used.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-141223, filed on Aug. 22, 2024, which is hereby incorporated by reference herein in its entirety.

What is claimed is:

1. A method of manufacturing a semiconductor apparatus using a substrate including a first device region and a second device region where different kinds of devices are formed, comprising:
selectively forming a first planarizing layer in the second device region where a surface height is lower than in the first device region; and
collectively forming a second planarizing layer across the first device region and the second device region after the first planarizing layer is formed,
wherein the first planarizing layer is formed by a planarization process of planarizing a composition supplied to the second device region by using a member having a flat surface.

2. The method according to claim 1, wherein
the first planarizing layer is formed in the second device region by the planarization process so as to reduce a difference in surface height between the first device region and the second device region.

3. The method according to claim 1, wherein
the planarization process includes supplying the composition to the second device region, curing the composition in a state in which the flat surface of the member is in contact with the composition in the second device region, and separating the member from the cured composition.

4. The method according to claim 1, wherein
the second planarizing layer is formed by a spin coating method.

5. The method according to claim 1, wherein
the first device region is a region where one of a color image capturing device and a color display device is formed, and the second device region is a region where one of a monochrome image capturing device and a monochrome display device is formed.

6. The method according to claim 5, further comprising
forming a color filter layer in the first device region, and
wherein the first planarizing layer is formed in the second device region by the planarization process so as to reduce a difference between a surface height of the color filter layer in the first device region and a surface height of the first planarizing layer in the second device region.

7. The method according to claim 6, further comprising
collectively forming a lower planarizing layer on the substrate across the first device region and the second device region,
wherein the color filter layer is formed on the lower planarizing layer in the first device region, and the first planarizing layer is formed on the lower planarizing layer in the second device region.

8. The method according to claim 5, further comprising
forming a lens array on the second planarizing layer for each of the first device region and the second device region.

9. The method according to claim 1, wherein
a surface height of the substrate is lower in the second device region than in the first device region.

10. The method according to claim 9, wherein
the first planarizing layer is formed in the second device region by the planarization process so as to reduce a difference between a surface height of the substrate in the first device region and a surface height of the first planarizing layer in the second device region.

11. The method according to claim 9, wherein
each of the first device region and the second device region is a region where one of an image capturing device and a display device is formed, and
the method further comprises forming a color filter layer on the second planarizing layer for each of the first device region and the second device region, and collectively forming an upper planarizing layer across the first device region and the second device region after the color filter layer is formed.

12. The method according to claim 11, further comprising
forming a lens array on the upper planarizing layer for each of the first device region and the second device region.
